(19) United States
(12) Patent Application Publication
(10) Pub. No.: US 2006/0154397 A1
(43) Pub. Date: Jul. 13, 2006

(54) Method for manufacturing a display device and method for forming a pattern

(75) Inventors: Mitsuasa Takahashi, Kawasaki (JP); Yoichi Murayama, Kawasaki (JP)

Correspondence Address: SUGHRUE MION, PLLC, 2100 PENNSYLVANIA AVENUE, N.W., SUITE 800, WASHINGTON, DC, 20037, US

(73) Assignee: NEC LCD TECHNOLOGIES, LTD.

(21) Appl. No.: 11/287,389

(22) Filed: Nov. 28, 2005

(30) Foreign Application Priority Data
Nov. 26, 2004 (JP) 2004-342870

(51) Int. Cl. H01L 21/00

(52) U.S. Cl. 438/34

(57) ABSTRACT

A method for manufacturing a display device is provided in which an a-Si semiconductor layer including signal terminal regions is formed in an island manner and the total parasitic capacitance is minimized while the increase of the number of process steps for photolithography is restricted. Signal lines, signal lead wires, signal terminals, part of drain electrodes, and part of source electrodes are formed using thin portions of a resist pattern. Small regions each from the position where a drain electrode and a source electrode oppose each other to positions beyond the width of a gate electrode are formed using the thick portions of the resist pattern. The resist pattern having these portions is used as a mask to etch a metal layer and a contact layer, and is reflowed to form a reflowed resist mask. The reflowed resist mask is used to form semiconductor islands.

This application claims priority to prior Japanese Patent Applications No. 2004-342870, the disclosures of which including specification, drawings and claims are incorporated herein by reference in its entirety.

### BACKGROUND OF THE INVENTION

1. Field of the Invention

The present invention relates to display devices, such as liquid crystal display (LCD) devices and electroluminescent (EL) display devices, and particularly to a method of manufacturing a display device and a method of forming a pattern for use in manufacturing a display device.

2. Description of the Related Art

It has been known that in the manufacture of LCD devices, the number of process steps for photolithography can be reduced by a method using a reflowed resist pattern prepared by reflowing a photoresist pattern. For reflowing a resist, the resist may be heated or chemically melted. The chemical reflow is superior to the heat reflow in spread of the resist and adhesion with the underlayer. The chemical reflow more easily allows separate resist pattern regions to associate with each other to form a one-piece resist pattern. Accordingly, in the process for manufacturing thin film transistors (TFTs) used in LCD devices, a reflowed resist pattern prepared by reflowing a resist pattern used in a front end step can be used for forming an amorphous silicon (a-Si) layer in an island manner under the source and drain electrodes and over the gate electrode, without performing an additional photolithography step.

Islands of a Si layer are generally formed not only in TFT regions, but also in areas underlying the signal lines (drain lines) extending from the drain electrodes to the signal terminals connecting the signal lines to an external circuit. In the known process of forming a resist pattern by reflow, the formation of a-Si islands in the TFT regions and under the signal lines increases the widths of the a-Si islands to be larger than the widths of the drain and the source electrode or the signal lines (Japanese Unexamined Patent Application Publication 2002-334830, FIGS. 5 to 7). Accordingly, the parasitic capacitance between the TFT region and the gate electrode is increased. As for the region underlying the signal line, the width of the a-Si layer is increased and, accordingly, the parasitic capacitance between the signal line and the pixel electrode is increased. The increase of parasitic capacitance negatively affects the signal transmission speed and the switching speed of the LCD device. In addition, potential of the signal line is easily transmitted to the pixel electrode due to the increased parasitic capacitance and, consequently, an uneven image is formed.

In order to minimize the increase of the width of the a-Si layer underlying the signal lines, a method has been known in which a metal film for forming the drain and source electrodes and the drain lines (signal lines) of the TFTs is patterned with a resist pattern having larger thickness portions in the regions used for forming drain/source electrodes. The larger thickness portions have a larger thickness than the portions used for forming the drain lines (signal lines). By forming a patterned metal layer by etching with this resist pattern and then reflowing the resist pattern, the spread of the resist in the thin portions can be small. Thus, the increase of the width of the a-Si layer can be minimized in the subsequent step of formatting the a-Si islands (Japanese Unexamined Patent Application Publication No. 2002-334830, FIGS. 8 to 11).

Another approach is also proposed in which the thin portions are removed by ashing the surface of the resist pattern before reflow, and remaining thick portions, whose thickness may have been reduced to some extent, is reflowed to form a reflowed resist pattern in only the regions for forming TFTs and the a-Si layer is thus formed in an island manner (Japanese Unexamined Patent Application Publication No. 2002-334830, FIGS. 12 to 15). In this method, the regions of the a-Si layer underlying the drain lines are formed into islands by etching using a drain line pattern. Consequently, the width of the a-Si layer underlying the drain lines does not increase and can be equal to that of the wire pattern.

Although those methods disclosed in Japanese Unexamined Patent Application Publication No. 2002-334830 can reduce parasitic capacitance in the TFT regions and the signal line regions, this patent document has not mentioned the problem of total parasitic capacitance, including that in the lead wires from the signal lines and in the signal terminals, or particularly how the a-Si layer is formed in an island manner.

### SUMMARY OF THE INVENTION

Accordingly, the present invention provides a method of manufacturing a display device in which an a-Si layer including signal terminal regions is formed in an island manner and the total parasitic capacitance is thus minimized while the number of the steps for photolithography is restricted.

The present invention also provides a method of forming a pattern suitably used in the method for manufacturing a display device.

According to an aspect of the present invention, there is provided a method of manufacturing a display device including pixel electrodes arranged in a matrix manner and TFTs supplying signals to the pixel electrodes on a surface of an insulating substrate. The method includes the step of forming a resist pattern on a multilayer composite formed on the insulating substrate. The multilayer composite includes gate electrodes and gate lines, a gate insulating layer, a semiconductor layer, and a metal layer. Subsequently, a patterned metal layer defining drain electrodes, source electrodes, signal lines, signal terminals, and signal lead wires, each connecting the corresponding signal line to the signal terminal is formed by etching the metal layer using the resist pattern as a mask. The resist pattern is reflowed to form a reflowed resist mask overlying the patterned metal layer and the gate electrodes and filling at least each space between the drain electrodes and the source electrodes. Then, the semiconductor layer is etched using the reflowed resist mask to form semiconductor islands under the drain electrodes, the source electrodes, the signal lines, the signal terminals, and the signal lead wires. A transparent protective insulating layer is formed over the patterned metal layer and regions at which the gate insulating layer is exposed, and an electrically conductive film is formed on the transparent protective insulating layer to form the pixel electrodes.

Preferably, the resist pattern has thick portions over part of the drain electrodes and part of the source electrodes, and thin portions over the other regions of the drain electrodes and source electrodes, the signal lines, the signal terminals, and the signal lead wires.

Preferably, the resist pattern having the thick portions and the thin portions is formed by exposing a photoresist through a photomask having light-shielding portions in a shape corresponding to the shape of the thick portions and semitransparent portions in a shape corresponding to the shape of the thin portions.

Preferably, the resist pattern is formed by exposing a photoresist through a photomask having light-shielding portions in a shape corresponding to the shape of part of the drain electrodes and source electrodes, and semitransparent portions in a shape corresponding to the shape of the other regions of the drain electrodes and source electrodes, the signal lines, the signal terminals, and the signal lead wires.

The electrically conductive film may be transparent. The transparent electrically conductive film can be used as the pixel electrode in a transmissive liquid crystal display.

The display device may be a liquid crystal display device or an electroluminescent display device.

According to another aspect of the present invention, a method for forming a pattern is provided. In the method, a resist pattern is formed on a multilayer composite formed on an insulating substrate. The multilayer composite includes a gate electrode, a gate line, a gate insulating layer, a semiconductor layer, a heavily doped semiconductor layer, and a metal layer. Subsequently, a patterned metal layer defining a drain electrode, a source electrode, a signal line, a signal terminal, and a signal lead wire connecting the signal line to the signal terminal is formed by etching the metal layer using the resist pattern. The resist pattern is reflowed to form a reflowed resist mask overlying the patterned metal layer and the gate electrode and filling at least a space between the drain electrode and the source electrode. The heavily doped semiconductor layer and the semiconductor layer are etched using the reflowed resist mask to form a semiconductor island under the drain electrode, the source electrode, the signal line, the signal terminal, and the signal lead wire. The resist pattern is formed by exposing a photoresist through a photomask having a light-shielding portion in a shape corresponding to the shape of part of the drain electrode and source electrode, and a semitransparent portion in a shape corresponding to the shape of the other regions of the drain electrode and source electrode, the signal line, the signal terminal, and the signal lead wire.

Preferably, the resist pattern has a thick portion over part of the drain electrode and part of the source electrode, and a thin portion over the other regions of the drain electrode and source electrode, the signal line, the signal terminal, and the signal lead wire.

In the method of the present invention, the signal lines, the signal lead wires, the signal terminals, part of the drain electrodes, and part of the source electrodes are formed using the thin portions of the resist pattern. The small regions from the position where the drain electrode and the source electrode oppose each other to positions beyond the width of the gate electrode are formed using the thick portions. The resist pattern having these portions is used as a mask to etch the metal layer and the contact layer, and is reflowed. The reflowed resist mask is used to form the semiconductor layer into islands. In the thin portions of the resist pattern for forming the signal lines, the signal lead wires, the signal terminals, part of the drain electrodes, and part of the source electrodes, the resist melted in the reflow step is prevented from flowing into the semiconductor layer and coating its surface. Thus, the areas of the resulting semiconductor islands can be prevented from increasing, including those of the signal lines, the signal lead wires, and the signal terminals.

Display devices manufactured by the method of the present invention can prevent the increase of the parasitic capacitance of the signal lines and the pixel electrodes, and accordingly, the potential of the signal line can be transmitted to the pixel electrode to form images without unevenness.

### BRIEF DESCRIPTION OF THE DRAWINGS

FIG. 1 is a schematic illustration of a TFT board of an LCD device according to an embodiment of the present invention;

FIG. 2 is a schematic plan view of one of the pixels shown in FIG. 1;

FIG. 3A is a plan view of the arrangement of parts and wires around a TFT and a pixel electrode of a pixel on the TFT board, and FIG. 3B is a sectional view taken along line A-A in FIG. 3A;

FIG. 4A is a detailed plan view of one of the signal terminals shown in FIG. 1, and FIG. 4B is a sectional view taken along line B-B in FIG. 4A;

FIGS. 5A to 5D are sectional views showing the step of forming layers on an LCD substrate in a TFT region;

FIGS. 6A and 6B are sectional views showing the step of forming layers on the LCD substrate in a signal terminal region;

FIG. 7A is a plan view showing a step following the step shown in FIG. 5D or 6B in the TFT region, and FIGS. 7B and 7C are sectional views showing the same step;

FIG. 8A is a plan view showing a step following the step shown in FIGS. 7A to 7C, and FIGS. 8B and 8C are sectional views showing the same step;

FIG. 9A is a plan view showing a step following the step shown in FIGS. 8A to 8C, and FIGS. 9B and 9C are sectional views showing the same step;

FIGS. 10A and 10B are sectional views showing a step following the step shown in FIGS. 9A to 9C;

FIGS. 11A and 11B are sectional views showing a step following the step shown in FIGS. 11A and 11B;

FIGS. 12A and 12B are sectional views showing a step following the step shown in FIGS. 11A and 11B;

FIGS. 13A and 13B are sectional views showing a step following the step shown in FIGS. 12A and 12B;

FIGS. 14A and 14B are sectional views showing a step following the step shown in FIGS. 13A and 13B;

FIGS. 15A and 15B are sectional views showing a step following the step shown in FIGS. 14A and 14B;

FIG. 16A is a plan view showing a step following the step shown in FIGS. 15A and 15B, and FIGS. 16B and 16C are sectional views showing the same step;

FIGS. 17A and 17B are plan views of part of a photomask used in an embodiment of the present invention,

### DESCRIPTION OF THE PREFERRED EMBODIMENT

An embodiment of the present invention will now be described with reference to the drawings.

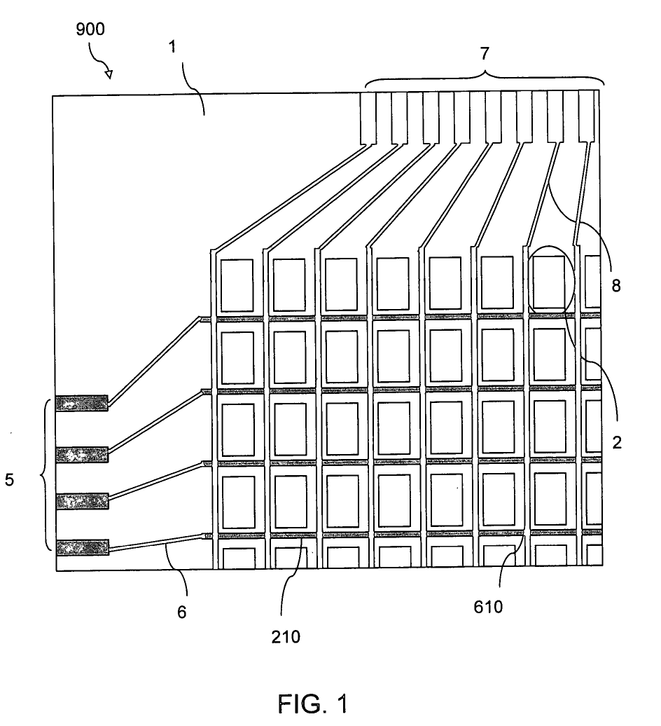

FIG. 1 shows part of a TFT board 900 of an LCD device according to an embodiment of the present invention. The TFT board includes pixels 2 arrayed in a matrix manner, scanning lines 210 extending parallel to each other in the transverse direction, and signal lines 610 extending parallel to each other in the vertical direction, on a glass substrate 1. The scanning lines are electrically connected to respective gate terminals 5 formed on a left part of the glass substrate 1 with gate lead wires 6. The signal lines 4 are connected to respective signal terminals 7 formed on the substrate with signal lead wires 8. The scanning lines, which are also called gate lines, each continue to gate electrodes of TFTs. The signal lines, which are called drain lines, each continue to drain electrodes of the TFTs.

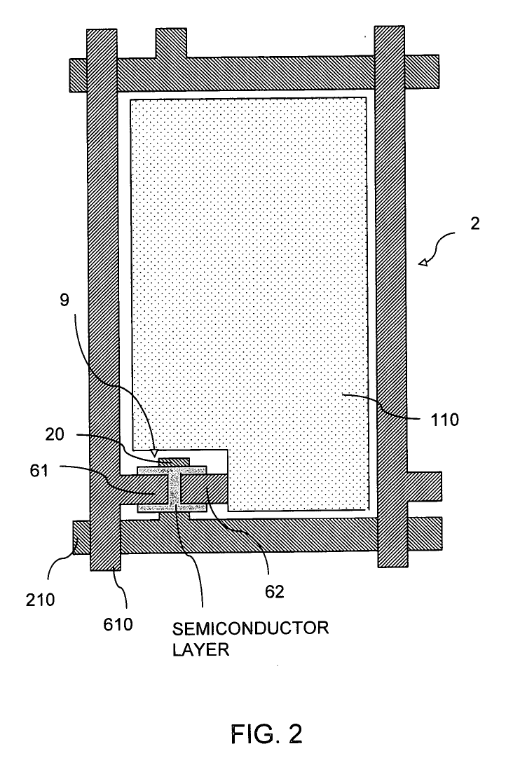

FIG. 2 is a schematic plan view of one of the pixels 2. Each pixel 2 includes a TFT 9 and a pixel electrode 110 and is surrounded by scanning lines 210 and signal lines 610. When a signal voltage is applied to a signal line while a scanning line is selected to apply a selected signal to the corresponding gate electrodes 20, the corresponding TFT is turned on. The signal voltage is thus supplied to the pixel electrode 110 through the drain electrode 61 and the source electrode 62.

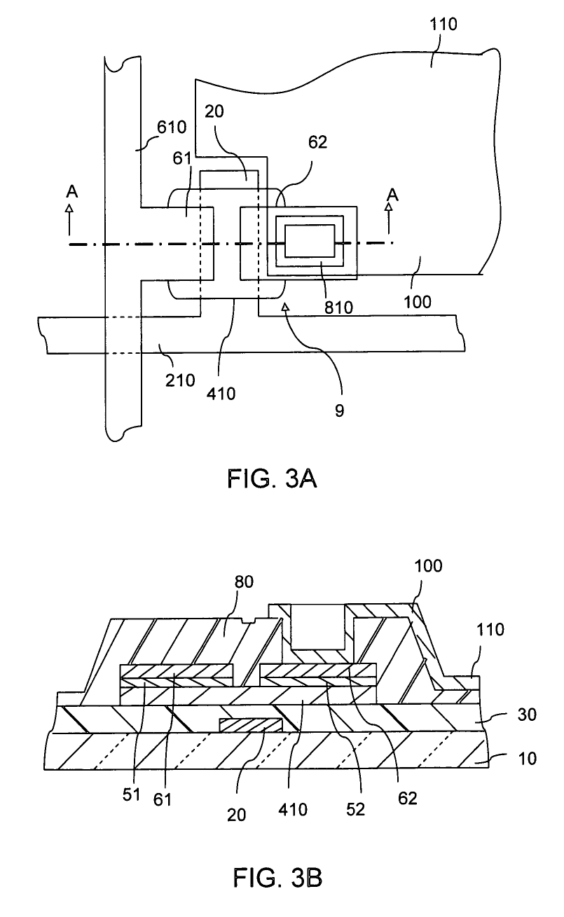

FIG. 3A is a plan view of the arrangement of the parts and wires around the TFT and the pixel electrode of a pixel on the TFT board, and FIG. 3B is a sectional view taken along line A-A in FIG. 3A.

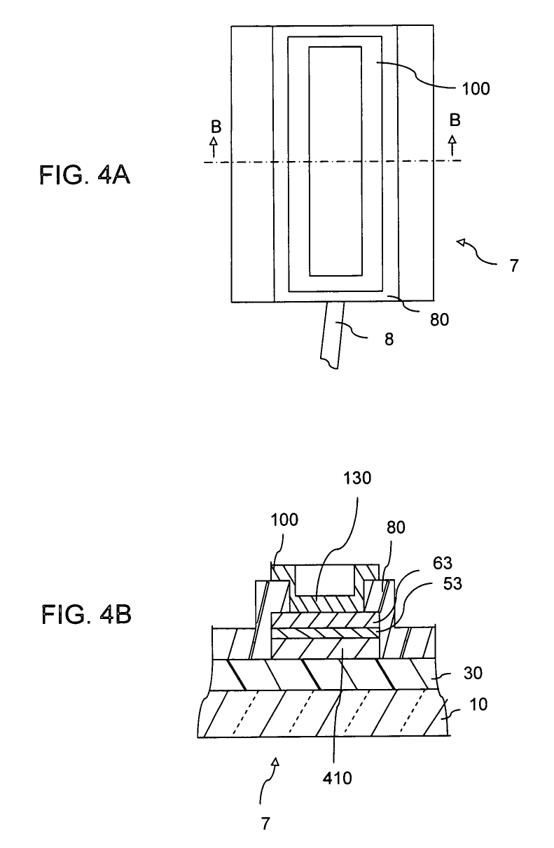

FIG. 4A is a detailed plan view of one of the signal terminals shown in FIG. 1, and FIG. 4B is a sectional view taken along line B-B in FIG. 4A.

As show in FIGS. 3A and 3B, the TFT 9 includes a set of a contact layer 51 and a drain electrode 61 and a set of a contact layer 52 and a source electrode 62, on a semiconductor island 410. The semiconductor island 410 overlies a gate electrode 20 with a gate insulating layer 30 therebetween. The source electrode 62 is connected to the pixel electrode 110 with a transparent conductive film 100 formed in a contact hole in a passivation layer 80. The gate electrode 20 is made of the same metal as the scanning line (gate line) 210. The drain electrode 61 is the same metal as the signal line (drain line) 610.

Turning to FIGS. 4A and 4B, the signal terminal 7 includes the semiconductor island 410, a contact layer 53, a metal layer (metal electrode for the signal terminal) 63, and the passivation layer 80, on the insulating layer 30. A contact hole is formed in the passivation layer to expose the metal layer 63. The transparent conductive film 100 extends so as to overlie the metal layer 63. Thus, the signal terminal 7 is completed and used for a connection with an external terminal. The semiconductor island 410 has substantially the same width as the contact layer 53 and the metal electrode 63. The signal lead wire 8 has the same multilayer structure as that of the signal terminal from the glass substrate 10 to the passivation layer 80. The metal layer, the contact layer, and the semiconductor island have substantially the same width as each other. The signal lead wire 8 is different from the signal terminal 7 in that the contact hole and the transparent conductive film 100 are not formed and the width is not always constant over the entire length, depending on the positional relationship between the signal line and the signal terminal.

The semiconductor islands 410 are formed from a semiconductor layer by the following process. In the process according to the present embodiment, the signal lines, the signal lead wires, the signal terminals, part of the drain electrodes, and part of the source electrodes are formed using thin portions of a resist pattern. The small regions from the position where the drain electrode and the source electrode oppose each other to positions beyond the width of the gate electrode are formed using thick portions. The resist pattern having these portions is used as a mask to etch the metal layer and the contact layer, and is reflowed. The reflowed resist mask is used to form the semiconductor layer into islands. In the thin portions of the resist pattern for forming the signal lines, the signal lead wires, the signal terminals, part of the drain electrodes, and part of the source electrodes, the resist melted in the reflow step is prevented from flowing into the semiconductor layer and coating its surface. Thus, the increase in area of the resulting semiconductor islands can be prevented.

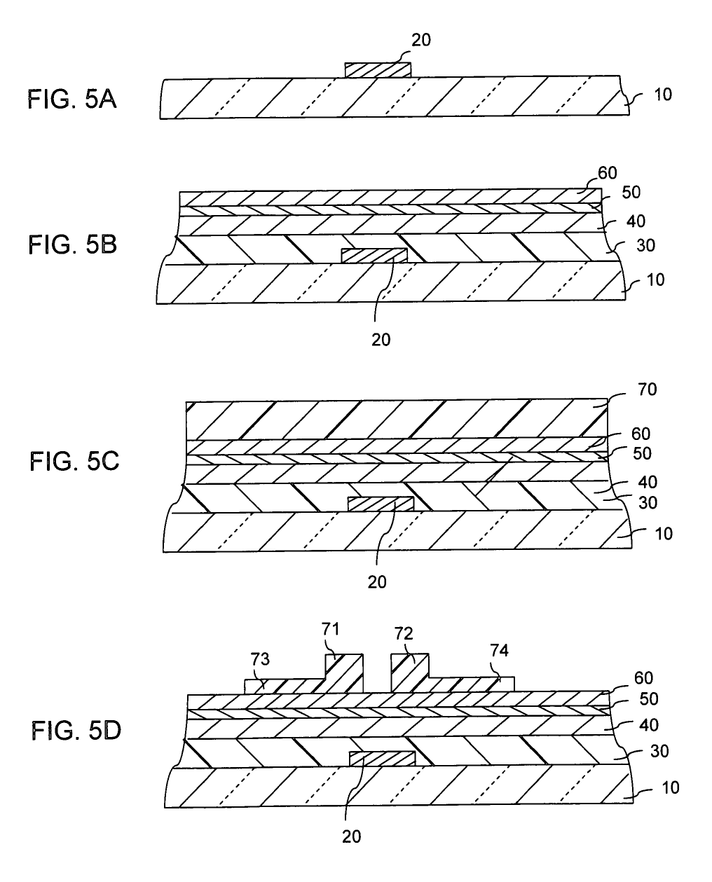

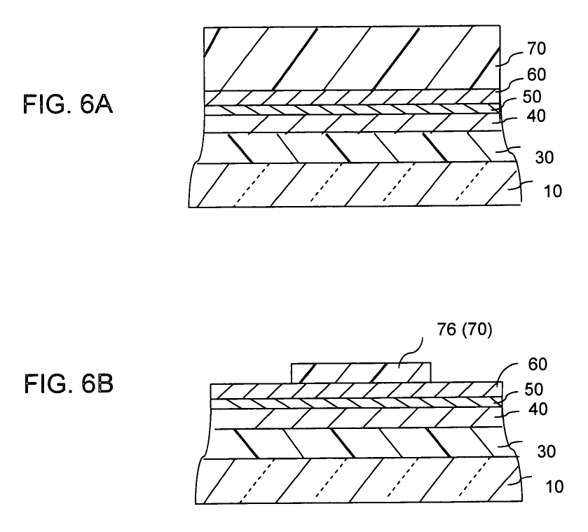

FIGS. 5A to 5D and 6A and 6B are sectional views of a TFT region and a signal terminal region in the step of forming the TFT board.

In FIG. 5A, the gate electrode 20 is formed from a metal film on the glass substrate 10 by known photolithography, simultaneously with the gate line (not shown in FIGS. 5A to 5D). The metal film is formed of aluminum, molybdenum, or chromium, or an alloy mainly containing these metals, to a thickness of about 100 to 400 nm by sputtering. Turning to FIG. 5B, the gate insulating layer 30 made of, for example, silicon nitride, the semiconductor layer 40 made of amorphous Si (a-nSi), and an ohmic contact layer 50 made of heavily doped n⁺ amorphous Si (a-n⁺Si) are formed to thicknesses of about 400, 300, and 50 nm respectively on the structure show in FIG. 5A by plasma CVD. Further, a 250 nm thick metal layer 60 is formed of, for example, a Cr—Al alloy on the ohmic contact layer 50.

Then, a positive photoresist is applied onto the metal layer 60, followed by heating at 80 to 100° C. to remove the solvent in the photoresist. A photoresist layer 70 is thus formed as shown in FIG. 5C. The photoresist layer 70 is exposed to the optical image of a photomask defined by a predetermined pattern to form a latent image on the photoresist layer 70. The predetermined pattern of the photomask has light-shielding portions, semitransparent portions, and transparent portions on a mask substrate, as described in detail later. Consequently, the regions of the photoresist layer 70 corresponding to the light-shielding portions do not exposed to light. In the regions corresponding to the semitransparent portions, the latent image is formed in the surface of the photoresist layer 70 in a shallow depth. In the regions corresponding to the transparent portions, the latent image is formed in a depth equal to the depth of the photoresist layer 70. The exposed photoresist layer 70 is developed in an alkaline solution, so that the regions exposed to light are dissolved and the regions not exposed are left. Thus, the photoresist layer 70 is formed into a resist pattern having the thick portions 71 and 72 with a thickness of about 2 μm corresponding to the light-shielding portions, and the thin portions 73 and 74 with a thickness of about 0.2 to 0.7 μm corresponding to the semitransparent portions, as shown in FIG. 5D.

FIG. 6A is a sectional view of a portion intended to form the signal terminal of the multilayer structure prepared through the step shown in FIGS. 5A to 5C. Since the signal terminal does not have the gate electrode, the structure shown in FIG. 6A does not have the metal film for forming the gate electrode 20. The pattern of the photomask for forming a resist pattern used in this region has semitransparent portions and transparent portions. The photoresist layer 70 in the signal terminal region is exposed through the photomask and developed. Thus, a thin resist pattern 76 is formed in the regions corresponding to the semitransparent portions and the photoresist layer 70 in the other regions is removed, as shown in FIG. 6B. In the signal lead wire region as well, a thin resist pattern is formed by exposure through a photomask having a pattern with semitransparent portions according to the widths of the wires.

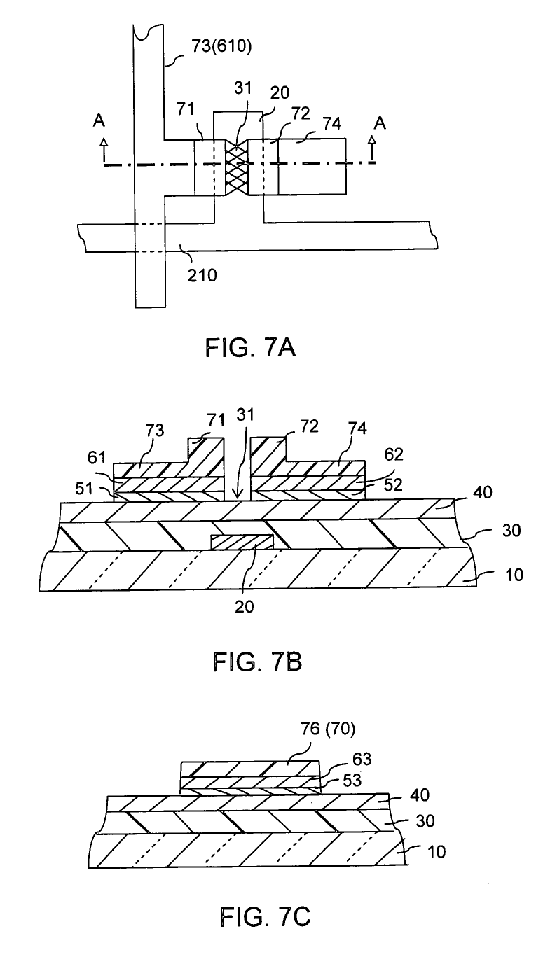

FIGS. 7A to 7C show the structure of the TFT region in a step following the step shown in FIG. 5D. The structure having the resist pattern shown in FIG. 5D is exposed using the resist pattern as a mask to dry-etch the metal layer 60 and its underlying a-n⁺Si ohmic contact layer 50 until the a-nSi semiconductor layer 40 is exposed, as shown in FIGS. 7A and 7B. Thus, the drain electrode 61, the drain line 610, and the contact layer 51 are formed whose shapes are defined by the shape of the resist pattern. Also, the source electrode 62 and the contact layer 52 are formed in the same manner. At this point, the a-n⁺ Si ohmic contact layer 50 is divided into contact layers 51 and 52 by the etching, thereby forming a channel 31 on the a-nsi semiconductor layer 40. In the signal terminal region, the metal electrode (metal layer) 63 and the contact layer 53 are formed in a shape defined by the shape of the resist pattern 76 by the etching, as shown in FIG. 7C. The signal lead wire also has the metal layer and the contact layer whose shapes are defined by the shape of the resist pattern 76. In the plan view of FIG. 7A, in which the glass substrate 10 and the gate insulating layer 30 are omitted, the ohmic contact layers 51 and 52, the drain electrode 61, and the source electrode 62 are hidden under the resist pattern. The sectional views designated by the same number with a letter A, B, or C, used in the following description show the TFT region and the signal terminal region in the same process step, unless otherwise stated.

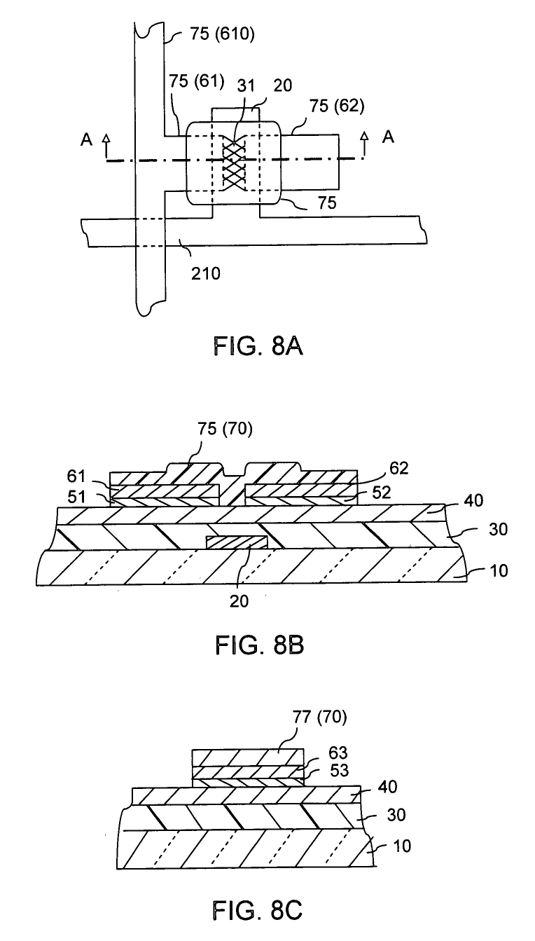

FIGS. 8A to 8C show the following step. The structure shown in FIGS. 7A to 7C having the resist pattern is exposed to the vapor of an organic solvent to reflow the resist pattern. The organic solvent may be acetone or propylene glycol monoethyl ether. These chemicals make short time vapor exposure of about 0.1 to 3 minutes possible. The organic solvent permeates the resist pattern and melts it, thus reflowing the resist pattern. As a result, the thick portions 71 and 72 of the resist pattern spread to increase the area. The thin portions 73, 74, and 76 of the resist pattern do not spread because of the surface tension of the melted thin layer. FIGS. 8A and 8B show the state of a reflowed resist mask 75 in the TFT region formed by reflowing the resist pattern. FIG. 8C shows a reflowed resist mask 77 in the signal terminal region. The reflowed resist mask in the signal lead wire region is in the same state as the signal terminal region.

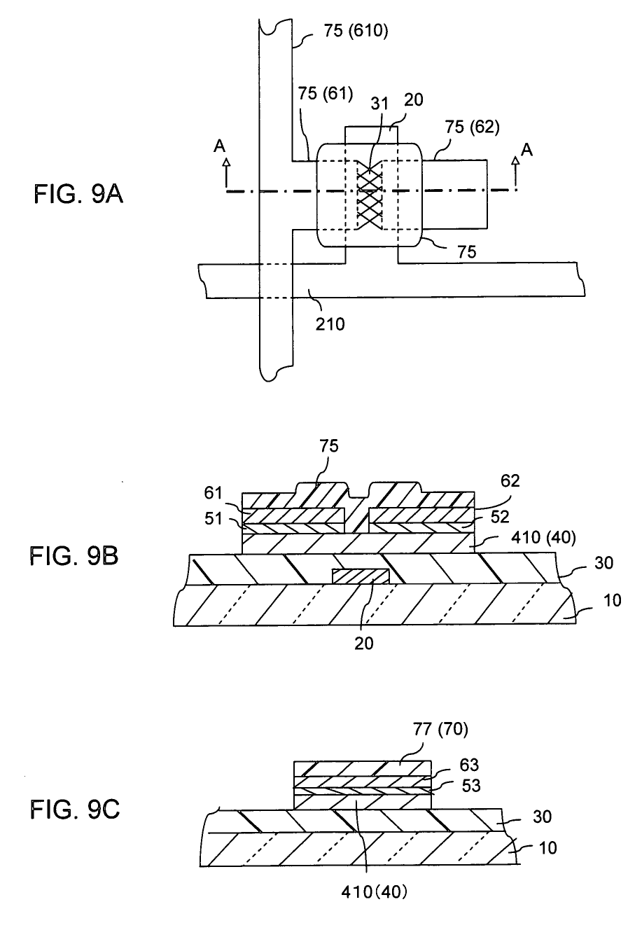

Then, in the structure shown in FIGS. 8A to 8C, the regions of the semiconductor layer 40 not having the reflowed resist masks are subjected to reactive ion etching, using the reflowed resist masks 75 and 77 to expose the surface of the insulating layer 30, thereby forming the semiconductor island 410, as shown in FIGS. 9B and 9C. The region of the semiconductor island 410 corresponding to the thick portions of the reflowed resist mask 75 extends beyond the widths of the drain electrode 61 and the source electrode 62. On the other hand, the regions of the semiconductor island 410 corresponding to the thin portions of the resist pattern have substantially the same area as the thin portions. FIGS. 9A and 9B show the resulting structure of the TFT region in plan view and sectional view respectively, and FIG. 9C shows the resulting structure of the signal terminal region in sectional view.

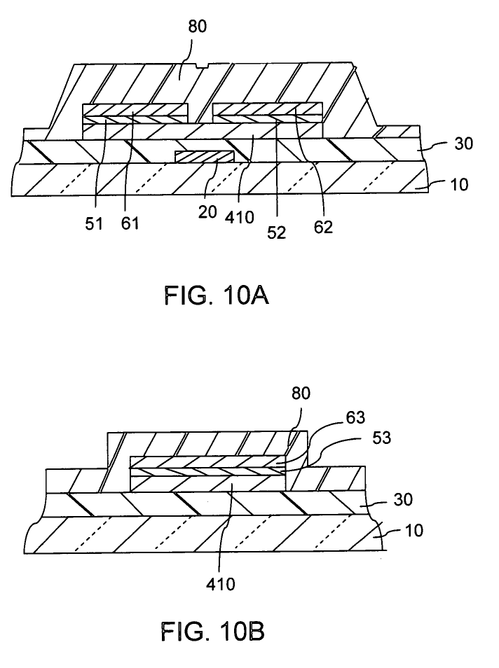

Turning to FIGS. 10A and 10B, the reflowed resist masks 75 and 77 shown in FIGS. 9A to 9C are removed and the exposed surface is entirely coated with the passivation layer 80 made of silicon nitride or silicon oxide. FIG. 10A shows the TFT region having the passivation layer 80 and FIG. 10B shows the signal terminal region having the passivation layer 80.

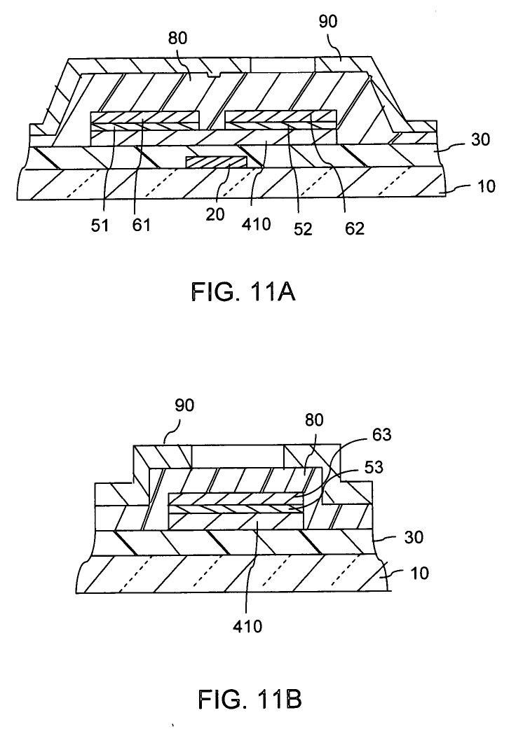

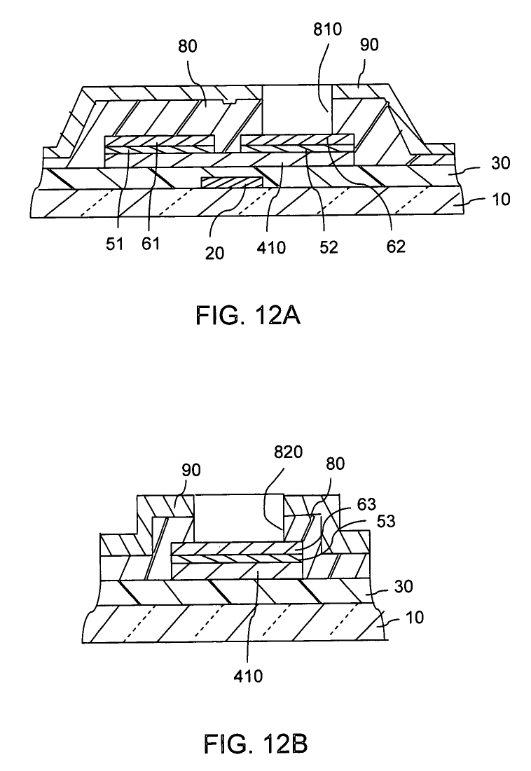

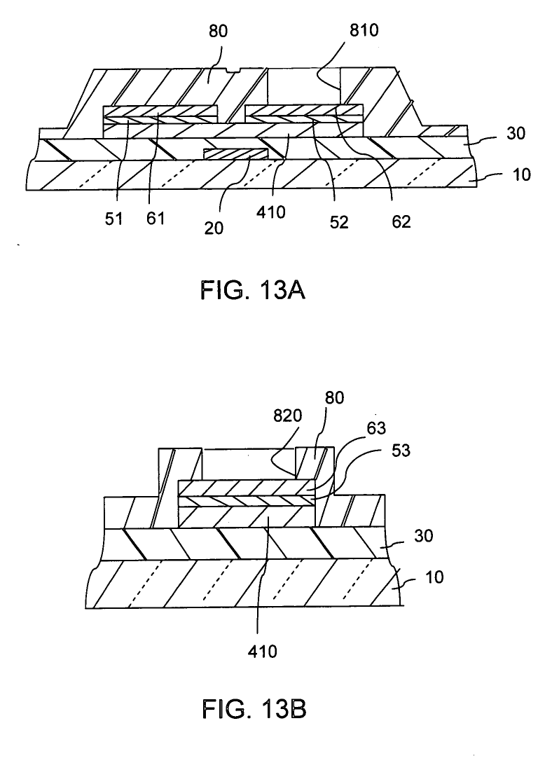

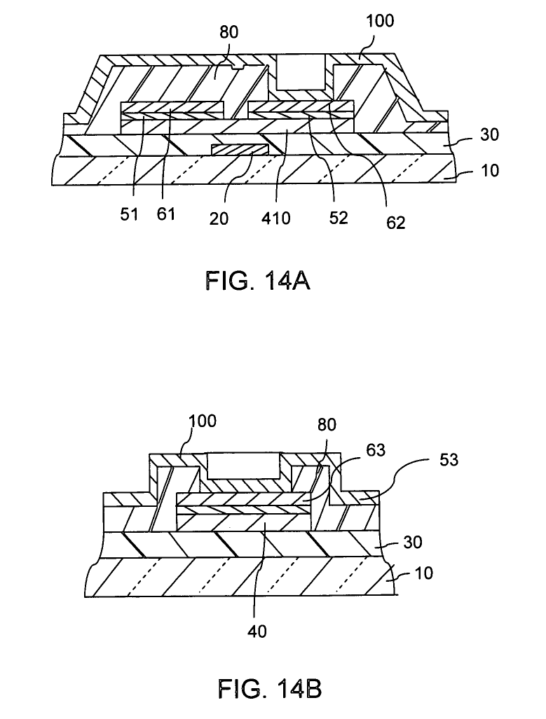

Then, a resist is applied onto the passivation layer 80 of the structure shown in FIGS. 10A and 10B, and the regions of the resist overlying the source electrode 62 in the TFT region and the metal electrode 63 in the signal terminal region are exposed and developed, followed by removing the resist in these regions. Thus, a resist mask 90 is formed in a pattern shown in FIGS. 11A and 11B. The passivation layer 80 is etched using the resist mask 90 to form contact holes 810 and 820, as shown in FIGS. 12A and 12B, and the resist mask 90 is removed, as shown in FIGS. 13A and 13B. Turing then to FIGS. 14A and 14B, an ITO transparent conductive film 100 is formed over the entire surface of the structure.

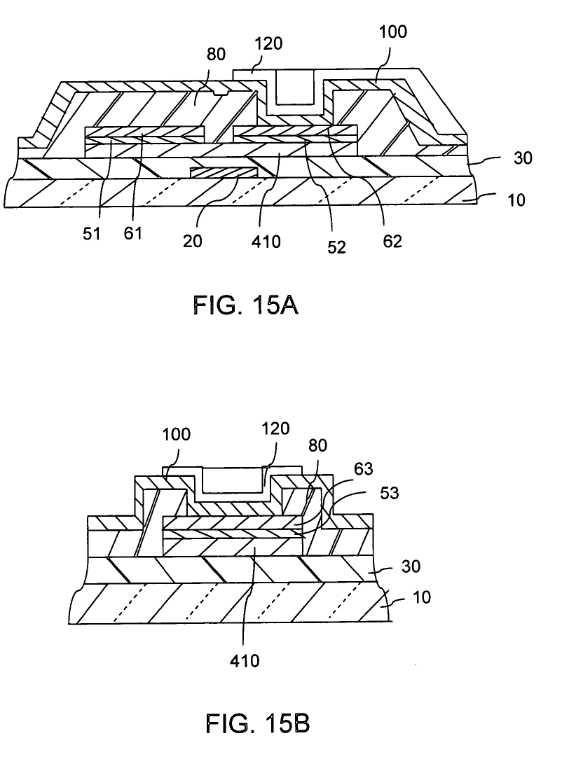

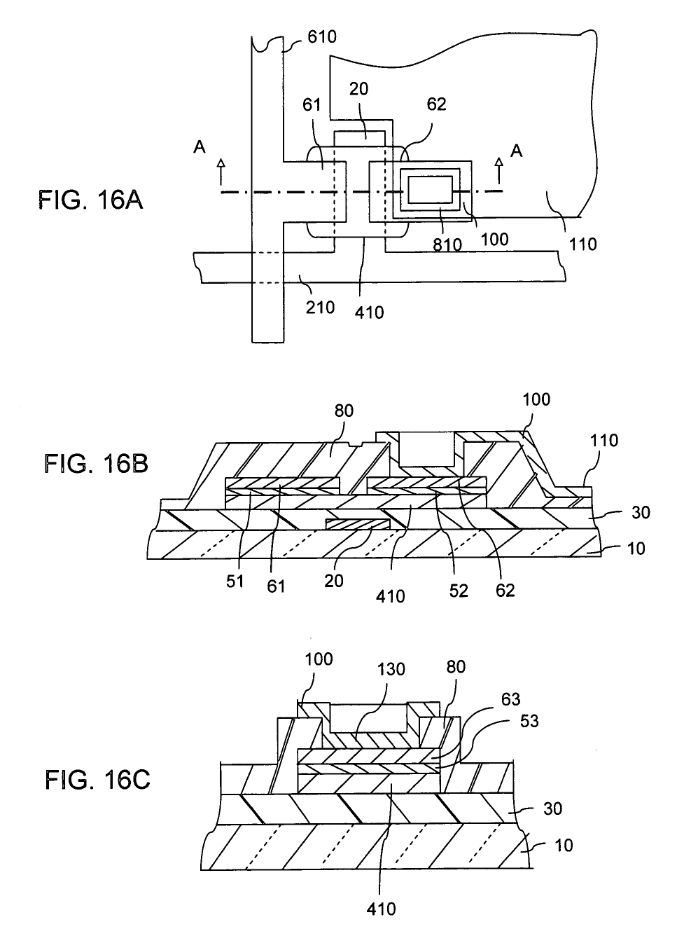

Further, a resist is applied over the entire surface of the transparent conductive film 100 and is subjected to photolithography to form a resist mask 120 shown in FIGS. 15A and 15B, The transparent conductive film 100 is etched using the resist mask 120 to remove the regions not covered with the resist mask 120, and then the resist mask 120 is removed. Thus, the pixel electrode 110 shown in FIGS. 16A and 16B and the transparent electrode 130 shown in FIG. 16C are formed in the TFT region and the signal terminal region, respectively. Therefore, the resist mask 120 is formed on the pixel electrode 110 and the transparent conductive film 100 in the contact hole over the source electrode 62, on the region of the transparent conductive film 100 connecting to the pixel electrode 110, on the transparent conductive film 100 in the contact hole of the signal terminal region, on vicinities of these regions, but is not formed in the other regions.

The TFT board thus completed is provided with an alignment layer for liquid crystal orientation. An opposing substrate including a color filter, a black matrix, a transparent electrode, an alignment layer, and so on is opposed to the TFT board with a predetermined interval therebetween, and the space between the TFT board and the opposing substrate is filled with a liquid crystal material. Thus, a vertical electric field type liquid crystal display device is completed.

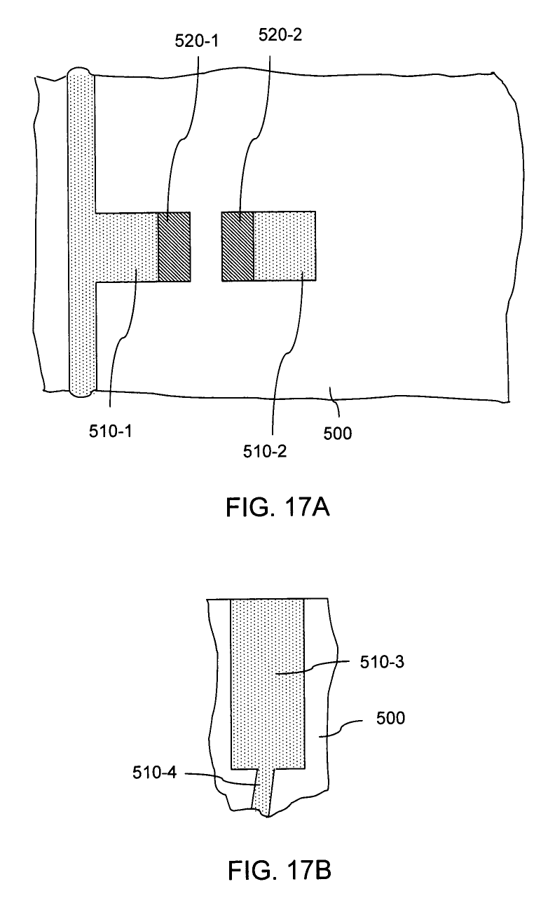

FIGS. 17A and 17B each show part of the photomask for forming the resist pattern having the thick portions and the thin portions in the steps shown in FIGS. 5D and 6B. FIG. 17A is the pattern of the photomask disposed in the TFT region, and FIG. 17B is the pattern of the photomask disposed in the signal terminal region. In FIG. 17A, the photomask has a pattern defined by light-shielding rectangular films 520-1 and 520-2 on a glass substrate 500. Also, semitransparent films 510-1 and 510-2 are disposed so as to continue to the light-shielding films 520-1 and 520-2, respectively. The light-shielding films 520-1 and 520-2 serve as light shields for the thick portions 71 and 72 of the resist pattern shown in FIG. 5D. The thick portions 71 and 72 are formed by exposure for forming optical images of the light-shielding films on the photoresist layer 70 and subsequent development. The semitransparent films 510-1 and 520-2 serve for the thin portions 73 and 74 of the resist pattern shown in FIG. 5D. The strip extending in the vertical direction of the semitransparent film 510-1 serves for the signal line (drain line) 610 shown in FIG. 7A. The region of the photoresist layer corresponding to the signal line is thus formed in a thin pattern by exposure for forming an optical image of the semitransparent film and subsequent development.

In FIG. 17B, the photomask for the signal terminal region has a pattern defined by semitransparent films 510-3 and 510-4 on the glass substrate 500. The semitransparent film 510-3 is used for forming the thin resist pattern 76 shown in FIG. 6B. The thin resist pattern 76 is formed by exposure for forming an optical image of the semitransparent film 510-3 on the photoresist layer 70 shown in FIG. 6A and subsequent development. The pattern defined by the semitransparent film 5104 shown in FIG. 17B is used for forming the thin resist pattern for the signal lead wire continuing to the signal terminal.

Preferably, in the resist pattern, the surface area of the thick portions is 10% or less of that of the thin portions, from the viewpoint of efficient use of the display region of the resulting display device. In the present embodiment, the signal lines, the signal lead wires, the signal terminals, part of the drain electrodes, and part of the source electrodes are formed using the thin portions 73, 74, and 76). The small regions from the respective edges of the drain electrode and the source electrode which oppose each other to positions beyond the width of the gate electrode are formed using the thick portions 71 and 72. The resist pattern having these portions is used as a mask to etch the metal layer and the contact layer, and is reflowed to form the reflowed resist masks 75 and 77. The reflowed resist masks 75 and 77 are used to form the semiconductor layer into semiconductor islands 410. Thus, in the method of the present embodiment, a photoresist layer is subjected to photolithography including steps of application, exposure, and development to form a mask, and the metal layer and the contact layer are etched using the mask to pattern the metal layer and the contact layer. Then, the mask is reflowed and the reflowed mask is used for etching a semiconductor layer underlying the metal layer and the contact layer. Hence, the method of the present invention forms two types of portions in a resist pattern through a process of photolithography, and the reflowed resist mask does not need specific positioning. In the thin portions of the resist pattern for forming the signal lines, the signal lead wires, the signal terminals, part of the drain electrodes, and part of the source electrodes, the surface tension of the resist melted in the reflow step prevents the resist from flowing into the semiconductor layer and coating its surface. Thus, the areas of the resulting semiconductor islands can be prevented from increasing, including those of the signal lines, the signal lead wires, and the signal terminals.

In the above-described embodiment, the metal layer and the contact layer are etched using a resist pattern, and after the resist pattern is reflowed, the semiconductor layer underlying the metal layer and the contact layer is etched using the reflowed resist mask. Alternatively, the metal layer may be etched to be patterned using the resist pattern, and after the resist pattern is reflowed to form a reflowed resist mask, the contact layer and the semiconductor layer underlying the metal layer may be etched using the reflowed resist mask, followed by removing the resist mask. Then, the region of the contact layer corresponding to the channel is removed by etching.

While the above-described embodiment illustrates a manufacture process for a vertical electric-field transmissive LCD device in detail, the method of the present invention may be applied to a manufacture process for a horizontal electric-field LCD device, a reflective LCD display device, or an EL display device.

In the above described embodiment, a pixel defines an image element, however, for color images, a picture element including a red, a blue, and a green pixel may define an image element.

What is claimed is:

1. A method of manufacturing a display device including pixel electrodes arranged in a matrix manner and TFTs supplying signals to the pixel electrodes on a surface of an insulating substrate, the method comprising the steps of:
forming a resist pattern on a multilayer composite formed on the insulating substrate, the multilayer composite including gate electrodes and gate lines, a gate insulating layer, a semiconductor layer, and a metal layer;
forming a patterned metal layer defining drain electrodes, source electrodes, signal lines, signal terminals, and signal lead wires, each connecting the corresponding signal line to the signal terminal, by etching the metal layer using the resist pattern as a mask;
reflowing the resist pattern to form a reflowed resist mask overlying the patterned metal layer and the gate electrodes and filling at least each space between the drain electrodes and the source electrodes;
etching the semiconductor layer using the reflowed resist mask to form semiconductor islands under the drain electrodes, the source electrodes, the signal lines, the signal terminals, and the signal lead wires;
forming a transparent protective insulating layer over the patterned metal layer and regions at which the gate insulating layer is exposed; and
forming an electrically conductive film on the transparent protective insulating layer to form the pixel electrodes.

2. The method according to claim 1, further comprising the step of etching part of the semiconductor layer, performed between the step of forming the patterned metal layer and the step of reflowing the resist pattern.

3. The method according to claim 1, further comprising the step of forming contact holes in the transparent protective insulating layer in regions overlying the source electrodes and the signal terminals.

4. The method according to claim 3, wherein the contact holes are coated with the electrically conductive film, thereby forming the signal terminals and electrically connecting the source electrodes to the respective pixel electrodes.

5. The method according to claim 1, wherein the resist pattern has thick portions over part of the drain electrodes and part of the source electrodes, and thin portions over the other regions of the drain electrodes and source electrodes, the signal lines, the signal terminals, and the signal lead wires.

6. The method according to claim 5, wherein the resist pattern having the thick portions and the thin portions is formed by exposing a photoresist through a photomask having light-shielding portions in a shape corresponding to the shape of the thick portions and semitransparent portions in a shape corresponding to the shape of the thin portions.

7. The method according to claim 1, wherein the resist pattern is formed by exposing a photoresist through a photomask having light-shielding portions in a shape corresponding to the shape of part of the drain electrodes and source electrodes, and semitransparent portions in a shape corresponding to the shape of the other regions of the drain electrodes and source electrodes, the signal lines, the signal terminals, and the signal lead wires.

8. The method according to claim 1, wherein the electrically conductive film is transparent.

9. The method according to claim 1, wherein the display device is a liquid crystal display device.

10. The method according to claim 1, wherein the display device is an electroluminescent display device.

11. A method of forming a pattern, comprising the steps of:
forming a resist pattern on a multilayer composite formed on an insulating substrate, the multilayer composite including a gate electrode, a gate line, a gate insulating layer, a semiconductor layer, a heavily doped semiconductor layer, and a metal layer;
forming a patterned metal layer defining a drain electrode, a source electrode, a signal line, a signal terminal, and a signal lead wire connecting the signal line to the signal terminal, by etching the metal layer using the resist pattern;
reflowing the resist pattern to form a reflowed resist mask overlying the patterned metal layer and the gate electrode and filling at least a space between the drain electrode and the source electrode; and
etching the heavily doped semiconductor layer and the semiconductor layer using the reflowed resist mask to form a semiconductor island under the drain electrode, the source electrode, the signal line, the signal terminal, and the signal lead wire,
wherein the resist pattern is formed by exposing a photoresist through a photomask having a light-shielding portion in a shape corresponding to the shape of part of the drain electrode and source electrode, and a semitransparent portion in a shape corresponding to the shape of the other regions of the drain electrode and source electrode, the signal line, the signal terminal, and the signal lead wire.

12. The method according to claim 11, wherein the resist pattern has a thick portion over part of the drain electrode and part of the source electrode, and a thin portion over the other regions of the drain electrode and source electrode, the signal line, the signal terminal, and the signal lead wire.
